(19) United States
(12) Patent Application Publication
(10) Pub. No.: US 2004/0124546 A1
(43) Pub. Date: Jul. 1, 2004

(54) Reliable integrated circuit and package

(76) Inventors: Mukul Saran, Richardson, TX (US); Rajesh K. Gupta, Carrollton, TX (US)

Correspondence Address: TEXAS INSTRUMENTS INCORPORATED, P O BOX 655474, M/S 3999, DALLAS, TX, 75265

(21) Appl. No.: 10/657,901

(22) Filed: Sep. 9, 2003

Related U.S. Application Data
(60) Provisional application No. 60/437,491, filed on Dec. 29, 2002.

(51) Int. Cl. H01L 23/48

(52) U.S. Cl. 257/787

(57) ABSTRACT

A packaged integrated circuit which includes a die 700 having a surface and corners separated by edges. The die surface includes depressions 600, 720 so that mold compound 114 covering the die surface fills the depressions. The filling of the depressions in the die surface enhances the adhesion of the mold compound to the die. The die can include bond pads 714, in which case the depressions can take the form of slots 720 in the bond pads. In addition, the depressions can take the form of trenches 600 at the surface of the die in a dielectric layer 703. The trenches can be at the die corners and along the die edges.

### BACKGROUND OF THE INVENTION

This invention is in the field of integrated circuits, integrated circuit packages, methods for manufacturing integrated circuits, and methods for packaging integrated circuits.

Packaged integrated circuits, particularly those in plastic packaging, are susceptible to thermal stress-related failures as a result of differences in coefficients of thermal expansion (CTE) in packaging components. In a typical package, mold compound is used to encapsulate the integrated circuit die, the substrate or leadframe upon which it is mounted, and the wire, ribbon, or ball connections between the integrated circuit die and the substrate. The CTE of the mold compound is typically a poor match to the integrated circuit die, as well as to the leadframe or substrate. As a consequence, there is a tendency for the mold compound to lose adhesion to the die and to delaminate from the die face during either the cooling of the package following the molding step or during subsequent thermal cycling. The initial delamination is exacerbated by continued thermal cycling, leading to an increase in the stresses on metal and passivation dielectric features on the die surface. These stresses can lead to metal lead deformation, cracking of the passivation layers on the die, and to cracking or lifting of wire bonds from bond pads on the die. A loss of integrity of the die passivation dielectric can allow water ingress, which eventually leads to catastrophic failure of the integrated circuit. Lifting of wire bonds, of course, also results in integrated circuit failure as does metal lead deformation. The corners and edges of the die are most susceptible to stress-related delamination since those features are typically furthest from the stress-neutral, central portion of the package.

Prior art attempts at solving the delamination problem include the use of a soft passivation film (typically polyimide) on the die surface. The film is relatively soft and sufficiently ductile to withstand delamination stresses between the mold compound and the die. However, the additional step required to deposit the soft film adds expense to the die fabrication process. Low-stress mold compounds (i.e. those with better CTE match to other package components) are also in use, but have so far not successfully eliminated problems related to delamination. Finally, since the problem is most severe on large integrated circuit die, one has the option of limiting the size of the die. This option has obvious commercial disadvantages. Therefore, there is a need in the industry for an inexpensive and effective approach to address the problem of thermal stress-related package delamination.

### BRIEF SUMMARY OF THE INVENTION

In one embodiment of the invention, a packaged integrated circuit is disclosed which includes a die having a surface and corners separated by edges. The die surface includes depressions so that mold compound covering the die surface fills the depressions. The filling of the depressions in the die surface enhances the adhesion of the mold compound to the die. The die can include bond pads, in which case the depressions can take the form of slots in the bond pads. In addition, the depressions can take the form of trenches at the surface of the die in a dielectric layer. The trenches can be at the die corners and along the die edges.

In another embodiment of the invention, a packaged integrated circuit includes a die including a stack of alternating patterned metal and dielectric layers; a trench in the stack through at least one of the dielectric layers; and mold compound covering the die and filling the trench. The stack can include a highest layer of patterned metal and a next-highest layer of patterned metal separated by an inter-level dielectric layer, wherein the trench is formed in the interlevel dielectric layer.

In still another embodiment of the invention, a packaged integrated circuit includes a die which includes bond pads. Each of the bond pads include a central bonding region and a peripheral region, and the peripheral region includes at least one slot such that mold compound can fill the slot to enhance the adhesion of the mold compound to the die surface. A passivating dielectric layer can be formed over the die to conformally cover the bond pad and the slots prior to molding the integrated circuit in encapsulating resin.

In yet another embodiment of the invention, the surface of the die includes step-like projections, which are covered with a passivating dielectric. The passivating dielectric has sloped edges to reduce the lateral forces the projections may encounter should the mold compound delaminate from the die surface.

An advantage of the invention is that it enhances adhesion of mold compound to the die, therefore decreasing the likelihood of delamination. If delamination does occur, the invention helps prevent damage to metal and dielectric layers that can lead to the catastrophic failure of the integrated circuit.

### BRIEF DESCRIPTION OF THE SEVERAL VIEWS OF THE DRAWINGS

The drawings are intended to assist in understanding embodiments of the invention. One skilled in the art will appreciate that the drawings are not to scale; in particular, the vertical dimension is typically exaggerated to better show the details of the embodiments.

FIG. 1 is a cross-sectional view of a prior art packaged integrated circuit.

FIG. 2 is a plan view of the prior art integrated circuit of FIG. 1.

FIG. 3a is a cross-sectional view of a prior art packaged integrated circuit prior to delamination of the mold compound from the die surface.

FIG. 3b is a cross-sectional view of the prior art packaged integrated circuit of FIG. 3a after initial delamination of the mold compound from the die surface.

FIG. 3c is a cross-sectional view of the prior art packaged integrated circuit of FIGS. 3a and 3b after total delamination of the mold compound from the die surface.

FIG. 4 is a plan view of the bond pads and metal leads of a prior art integrated circuit.

FIG. 5a is a plan view of the bond pads and metal leads of an embodiment of the invention.

FIG. 5b is a cross-sectional view of a bond pad of the embodiment of the invention shown in plan view in FIG. 5a.

FIG. 6a is a plan view of a incorporating an embodiment of the invention in which a trench is formed in the corner of the die to provide enhanced adhesion between the mold compound and the die surface.

FIG. 6b is a cross-sectional diagram of the dielectric/metal stack of the die shown in FIG. 6a.

FIGS. 7a to 7h are cross-sectional diagrams of a copper damascene embodiment of the invention in which the trench is formed prior to the deposition of a passivating dielectric layer.

FIGS. 8a to 8d are cross-sectional diagrams of a copper damascene embodiment of the invention in which the trench is formed using the mask used to form bond pad windows in the passivating dielectric.

FIGS. 9a to 9c are cross-sectional diagrams of an embodiment of the invention in which the sides of step-like projections on the surface of a die are shaped in order to reduce destructive lateral forces that may occur following delamination of mold compound from the die surface.

### DETAILED DESCRIPTION OF THE INVENTION

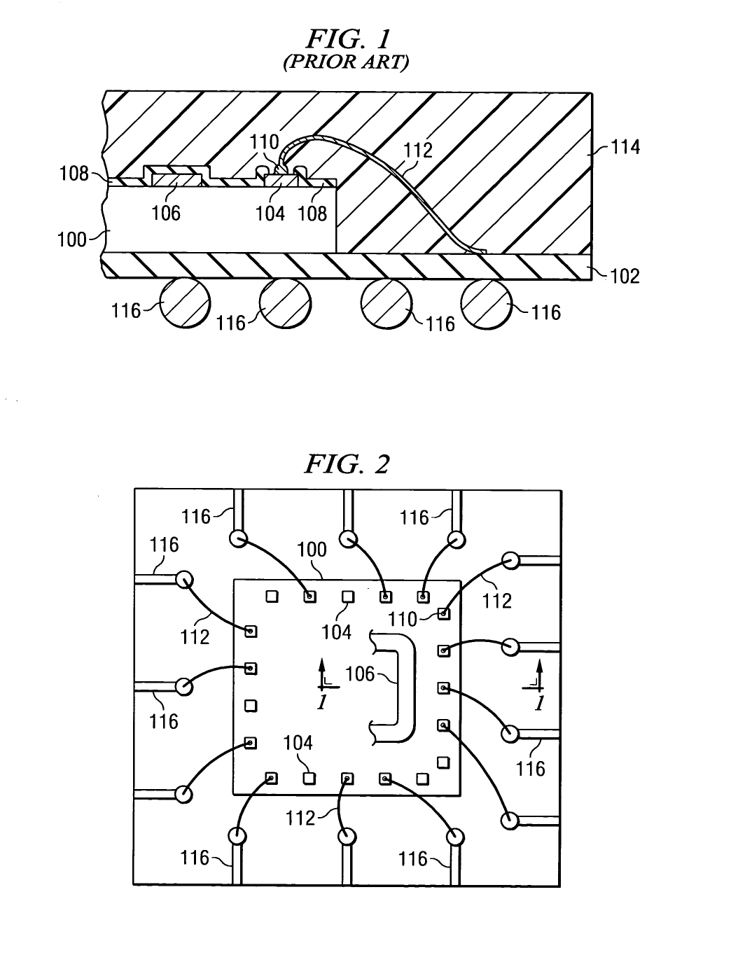

A cross-sectional diagram of a prior art packaged integrated circuit device is shown in FIG. 1. Semiconductor die 100 is mounted on substrate 102. Die 100 includes bond pads 104 and metal leads 106 on its top surface. A passivating dielectric layer 108 covers the top surface of die 100, except for openings over bond pads 104, where ball bonds 110 form connections (along with bond wire 112) between the integrated circuit on die 100 and metal traces (not shown) on substrate 102. Mold compound 114 encapsulates the top surface of substrate 102 as well as the semiconductor die 100 and other package components. External connections to the packaged integrated circuit are made by solder balls 116. A top or plan view of the structure is shown in FIG. 2 and makes clear the spatial relationships of the die 100, the bond pads 104, the metal leads 106, the ball bonds 110, the bond wires 112, and the conductive traces 116 on substrate 102.

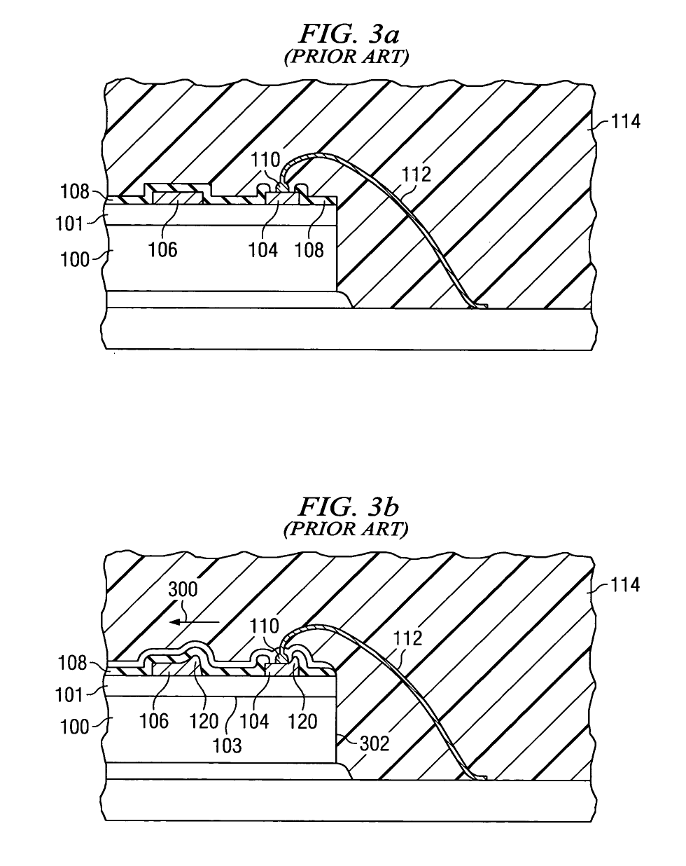

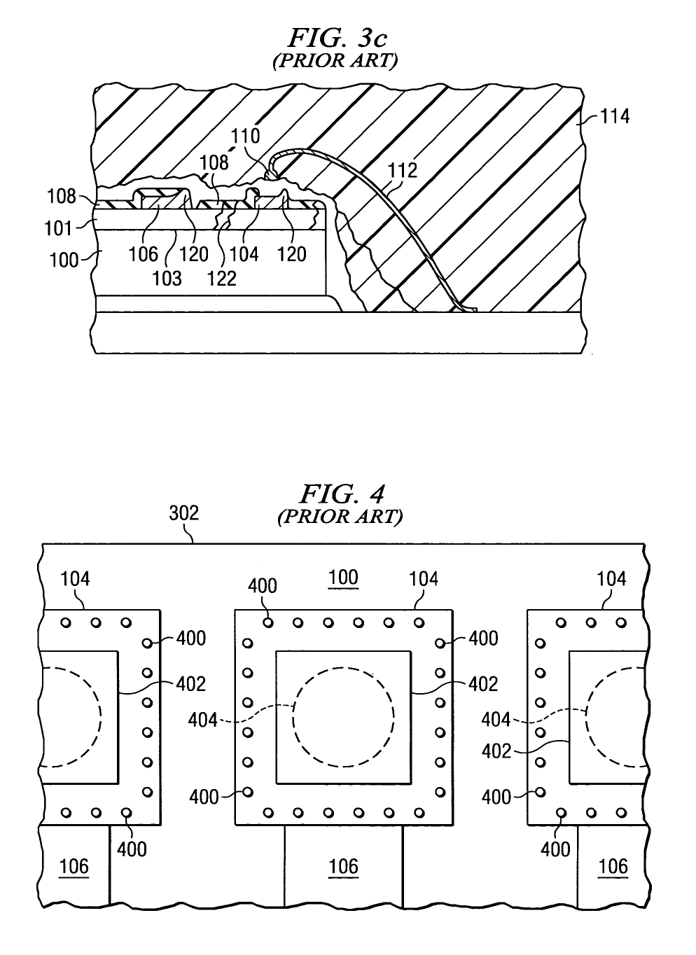

FIGS. 3a-3c are sketches showing the effects of thermal stress-induced delamination of the mold compound 114 from the surface of die 100. Note that the top surface of die 100 typically comprises a stack 101 comprising layers of metal traces separated by dielectric layers (references to “the die” hereinafter include stack 101 unless otherwise noted). Bond pads 104 and metal leads 106 are in the uppermost layer of metal traces. The intimate relationship of the mold compound 114 to the passivating dielectric 108 and to the bond wire 112 and ball bond 110 may be clearly seen in FIG. 3a. FIG. 3a illustrates the device as it is intended to appear in its final form.

FIG. 3b shows the beginning of delamination of mold compound 114 from the surface of the die 100 following one or more cooling cycles in which the mold compound contracts faster than the die due to the difference in CTE of the two materials. The mold compound tends to move toward the center and away from the edge 302 of the die 100 as shown by arrow 300. As mold compound 114 loses its adhesion to passivating dielectric 108, it separates slightly from the die and shifts away from the die edge 302. This movement often induces cracking in both the passivating dielectric 108 and in the relatively brittle dielectric stack 101, which can lead to moisture exposure at the die surface 103 and ultimately to failure of the integrated circuit. In addition to the cracking of the dielectric, another manifestation of the initial delamination process is the deformation of metal leads 106, die pads 104, and ball bonds 110 as the mold compound moves laterally across the die surface.

Further temperature cycling, along with the new freedom of the mold compound to shift relative to the die, results in even more deformation of the metal leads 106 and bond pads 104, and perhaps lifting of the ball bond 110 from the bond pad 104 as shown in FIG. 3c. Any cracking 122 of the dielectric layer 108 or the interlevel dielectric layers in stack 101 likely spreads deeper toward the surface 103 of the die 100 and further toward the die center. The result is the catastrophic failure of the packaged semiconductor device.

A plan view of detail of bond pads 104 is shown in FIG. 4. Bond pads 104 are connected to other circuitry (not shown) in the integrated circuit by metal leads 106. Through-holes or vias 400 connect the bond pad to metal layers beneath the metal layer in which the bond pads 104 and metal leads 106 are formed. The bond pads 104 and metal leads 106 as well as the surface of the die 100 (including metal/dielectric stack 101) are covered by passivating dielectric layer 108, the edge 402 of which is shown as an opening or window within the perimeter of the bond pads 104. An outline 404 of the intended location of ball bonds 110 is shown within the window. In a typical integrated circuit layout, the bond pads 104 are very close to the edge 302 of die 100 in order to facilitate connection of the pads 104 to external circuitry. As mentioned above, however, delamination stresses are greatest at points furthest from the die center, which means that die pads 104 experience some of the highest delamination stresses in the package.

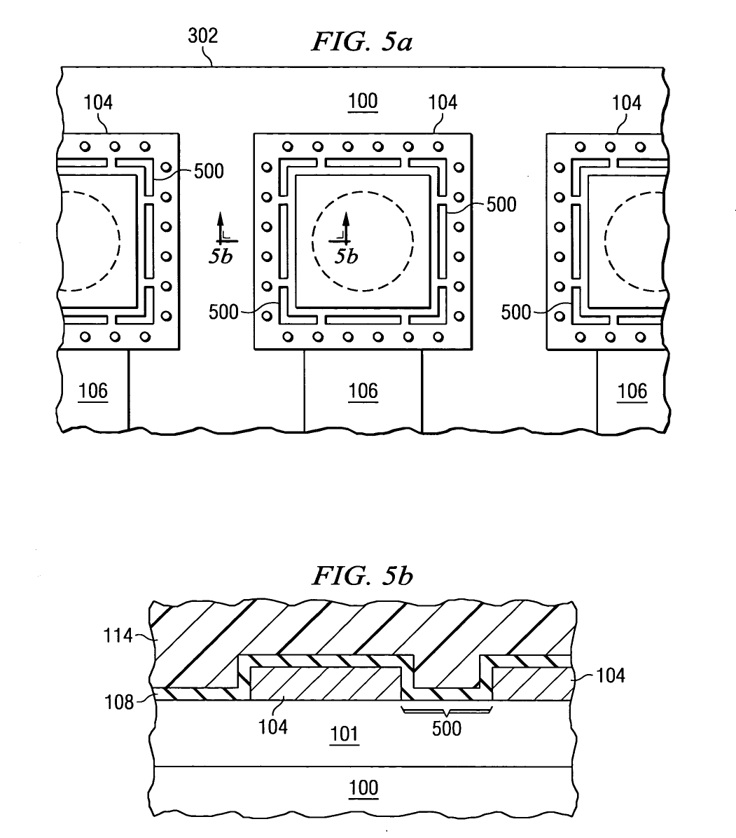

In an embodiment of the invention shown in FIG. 5a, bond pads 104 are modified to include depressions or slots 500 within the perimeter of the bond pad 104. As shown in cross-sectional view FIG. 5b, slot 500 extends through the bond pad metal to the underlying dielectric layer in the stack 101 that is formed over the surface of die 100. Slot 500 is easily formed during the step in which the highest metal layer in the stack 101 is patterned to form pads 104 and other metal features such as leads 106. Passivating dielectric 108 conformally covers the slot as well as the remainder of the die surface to prevent moisture ingress. In this embodiment, the passivating dielectric layer 108 comprises silicon nitride or a combination of layers of silicon nitride and silicon oxide. Slot 500 provides the advantage of additional area (i.e. texture) over which the adhesion of mold compound 114 may be anchored to passivating dielectric 108. Such enhanced adhesion at all bond pads around the edge 302 of the semiconductor die 100 helps reduce the possibility of the delamination of the mold compound from the die, and if delamination does occur, the additional adhesion helps prevent the effects of the delamination from propagating further toward the center of the die and toward the die surface.

The thickness of the bond pad metal is typically on the order of 1 μm and the passivating dielectric overlaps the edge of the bond pad by about 3 μm. Therefore, in this embodiment, the slot 500 is about 1.5 μm wide and about 1 μm deep, dimensions large enough to provide the additional grip between the mold compound and the die surface to help the reduce the possibility of delamination.

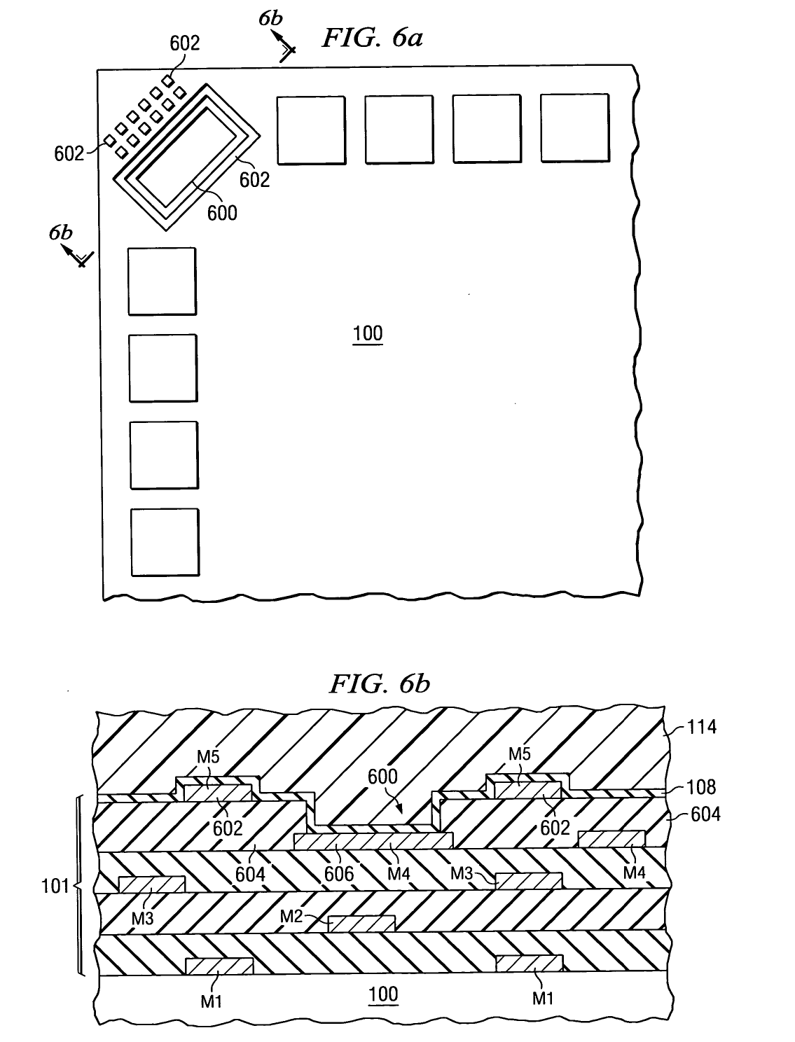

As noted above, the delamination stresses are highest near the chip edge. In fact, the greatest stresses occur at the chip corners. In another embodiment of the invention, shown in FIG. 6a, the corners of the surface of die 100 are modified to include depressions or trench structures 600 that provide even more texture to promote adhesion of the mold compound 114 to the die surface. In FIG. 6a, metal columns 602, work in conjunction with trench 600 to enhance adhesion. The trench is preferably as large as space allows, but is in this embodiment on the order of several tens of microns long and several tens of microns wide (e.g. 200 μm long by 100 μm wide). Its depth is dependent upon the etch technique used. In this embodiment, the trench extends through the dielectric layer in stack 101 that separates the top metal layer in which bond pads and metal leads are formed from the next highest metal layer in the stack, where is a dummy pad is formed to serve as the bottom of the trench. Alternatively, the trench could extend deeper into the dielectric stack or even into the surface of the die 100 itself. FIG. 6b, which is a cross-sectional diagram of the trench structure, shows the relationships of the highest metal layer (M5), the next-highest metal layer (M4), the interlevel dielectric layers within the stack, as well as the trench 600. The metal/dielectric stack 101 often consists of several layers of metal separated by dielectric layers. In the embodiment shown in FIG. 6b, there are five metal layers (M1-M5), the highest of which, M5, is used to form metal frame 602 around the trench structure 600. In this embodiment, trench 600 is formed in the upper interlevel dielectric layer 604 and bottoms onto dummy pad 606 formed in layer M4. But as mentioned above, the trench could extend deeper into the stack as well. Passivation dielectric layer 108 preferably conformally covers the trench as a moisture barrier. Mold compound 114 subsequently fills trench 600 and provides an anchor by which the mold compound adheres to the die.

In an alternative embodiment, trench structure 600 may be formed with a separate mask/etch step. Or, if the integrated circuit incorporates metal or polysilicon fuses in metal or polysilicon layers within the stack 101 (in M4, for example), the step in which the fuse is exposed for laser ablation by etching away any covering dielectrics can be used to form trench 600. The trench can be formed by simply modifying the fuse-patterning mask used in exposing the fuse to include the trench outline over the dummy pad 606, in which case the trench may be formed with no additional process steps. Note also that, although the trench 600 in this embodiment is formed at one or more corners of the die, similar trenches could also be formed along the edges or anywhere else on the die that may be susceptible to delamination.

In an alternative embodiment, if the trench is located in an area of the die (such as a corner or along the edge) that is not susceptible to water ingress or other sources of reliability concern, the trench can be formed using the mask used to form the windows (as shown in FIG. 4) in the passivating dielectric 108.

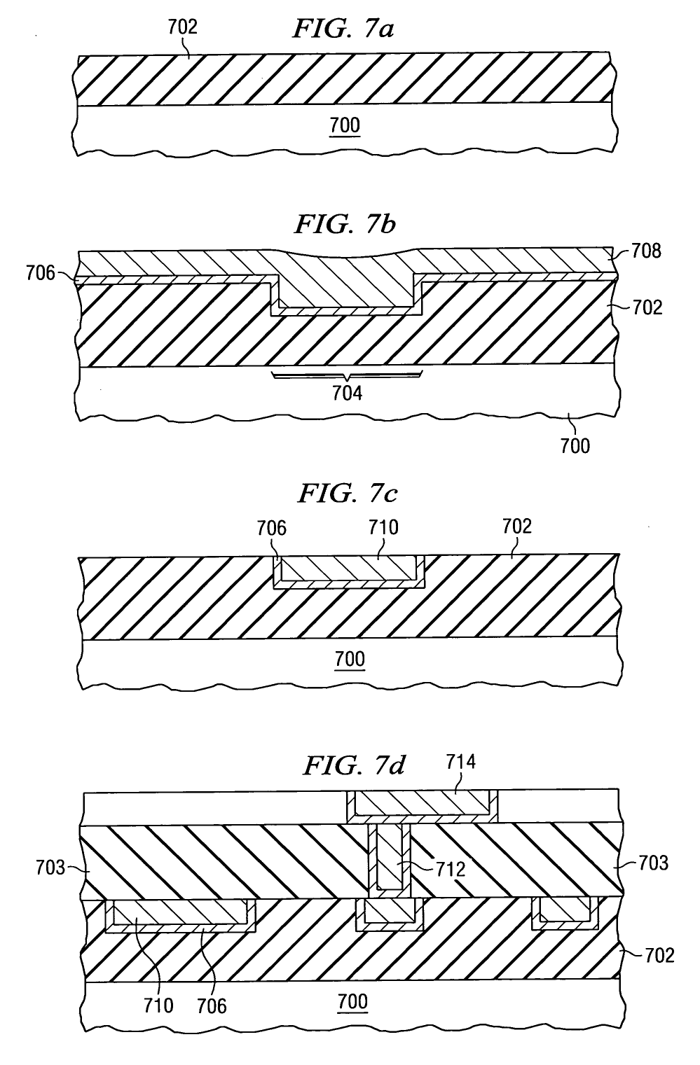

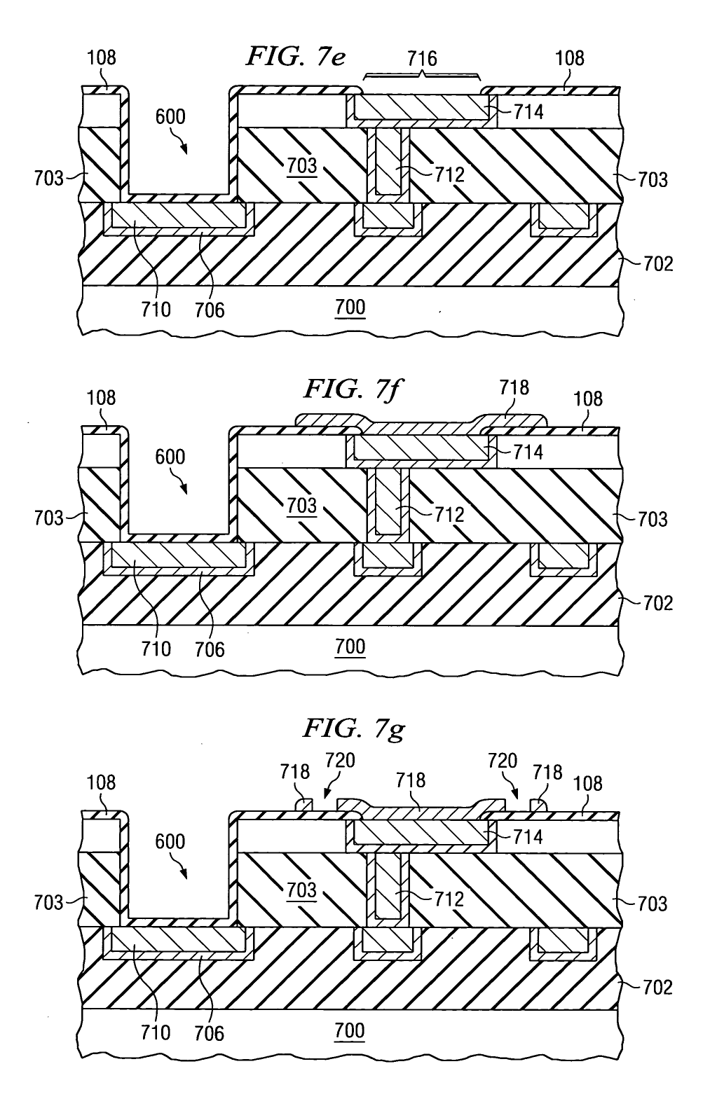

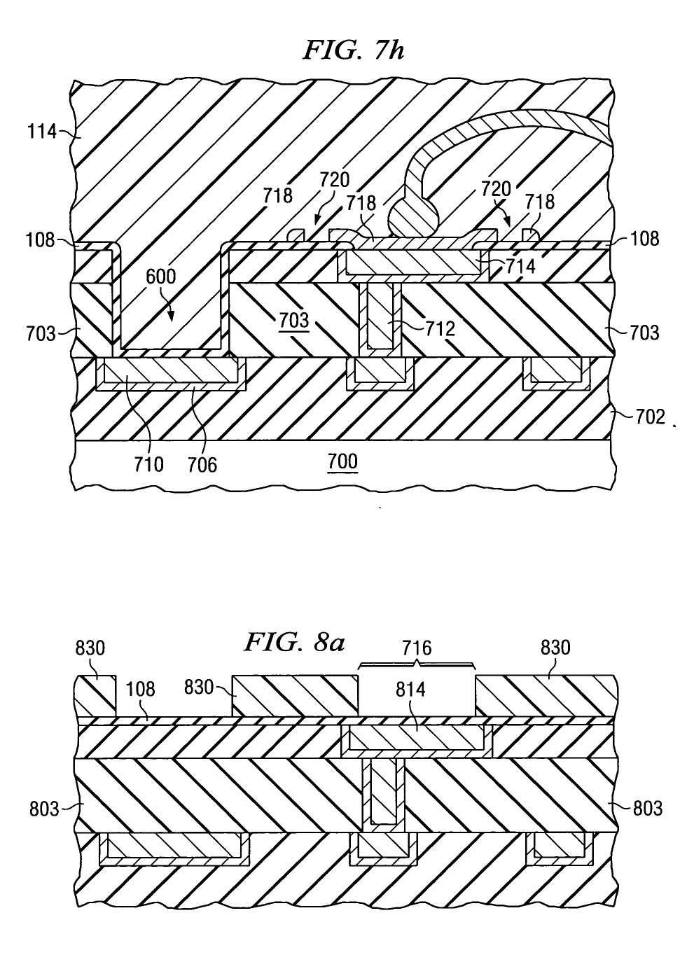

The trench-forming process described in the paragraphs above assumes use of a traditional metal system such as aluminum. The advantages of the invention may be had in a copper damascene metal system as well. Copper is more difficult to work with than aluminum as a metal for forming conductive leads on and over an integrated circuit as a result of the tendency of copper to diffuse widely throughout dielectric layers and into the semiconductor die, where it has a deleterious effect on transistor performance. As a consequence, copper leads are formed in a damascene process in which dielectric layers are applied, trench features are etched in the dielectric layer, a barrier metal is applied to coat the trenches, followed by copper in a thickness sufficient to fill the trenches. Excess copper is then removed from the surface of the dielectric layer with a chemical-mechanical etch step, for example, to leave the copper in the trench features. FIGS. 7a to 7b show various steps in such a copper damascene process in which inventive features are incorporated.

In FIG. 7a, dielectric layer 702 is formed over die 700 (or alternatively over another dielectric layer). In FIG. 7b, a trench 704 is etched in dielectric layer 702 in the pattern desired for copper leads. The trench is then lined with a copper barrier 706 such as tantalum nitride, for example. The barrier 706 is applied uniformly over the structure as shown in FIG. 7b. Copper 708 is then deposited to cover the barrier layer, in a thickness sufficient to completely fill trench 704. The copper and barrier layer are then removed from the surface of dielectric layer 702, with chemical-mechanical polishing, for example, as shown in FIG. 7c. The resulting structure is a copper trace 710 embedded in a surrounding dielectric layer 702. This process is repeated for vias 712 and subsequent metal layers 714 as shown in FIG. 7d. At this point in the process one is faced with a situation similar to that described above with regard to the traditional metal system. That is, one can either form trench 600 using a separate mask and etch step, or if the integrated circuit incorporates fuses in one of the lower metal layers in the stack, the mask can be modified to allow trench 600 to be formed in the step used to expose the fuses. This will avoid an extra masking, patterning, and etch step. The result of either of these approaches is shown in FIG. 7e, where trench 600 is shown with its lateral dimensions relatively compressed for convenience (recall its lateral dimensions are on the order of 200 μm, whereas bond pad 714 is approximately 1 μm above the next highest metal layer in the stack). Also shown in FIG. 7e, passivating dielectric 108 has been deposited over the entire structure and then etched to form window 716 over bond pad 714. In this embodiment, passivating dielectric 108 includes a silicon nitride layer in addition to a stress relieving layer such as benzocyclobutene (BCB) or polyimide.

Copper bond pads are difficult to bond to, so in this embodiment an aluminum cap 718 is formed over copper bond pad 714 as shown in FIG. 7f. Portions of aluminum cap 718 are then removed as shown in FIG. 7g to form slots 720 similar to those shown in FIG. 5a, features which enhance the adhesion of the mold compound to the die. The final structure is shown in FIG. 7h. Note that mold compound 114 fills trench 600 and slots 720.

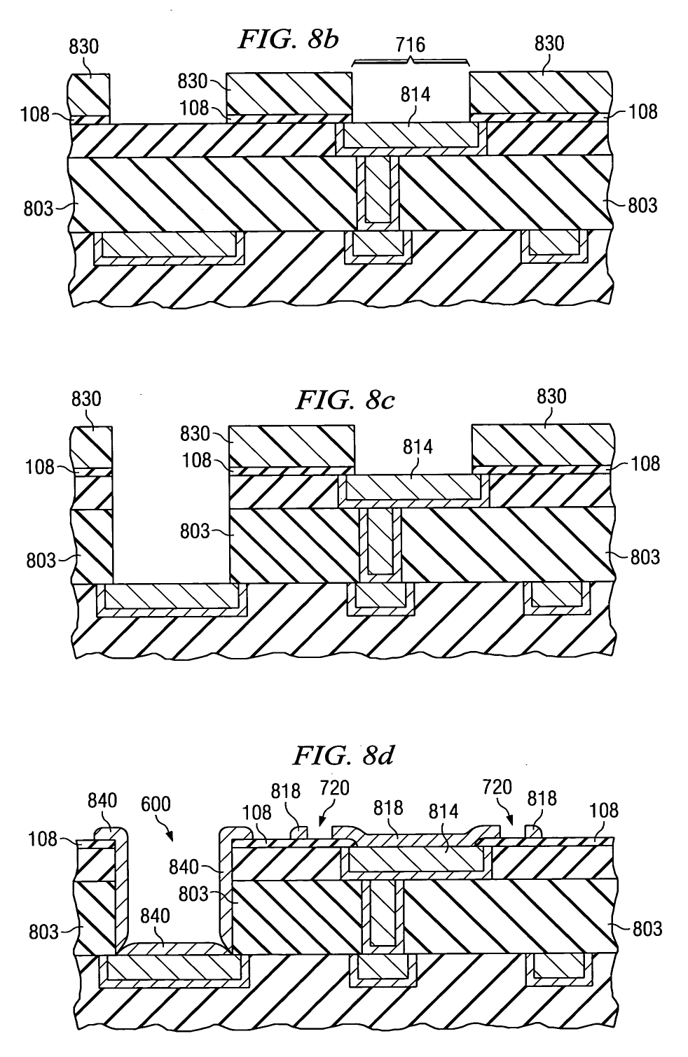

In a situation in which it is undesirable to use a separate mask/etch step to form the trench, and when the integrated circuit does not include fuses, the trench may be formed with the mask that is used in forming the window 716 in passivating dielectric layer 108 over bond pads 714. As mentioned above, the passivating dielectric 108 preferably comprises silicon nitride, so once the windows over the bond pads are formed in the passivating dielectric layer (the same step forms a window over the desired trench location), the same mask can be used with a different etchant to remove the interlevel dielectric layer (e.g. silicon dioxide, a silicate glass, or a low-k dielectric) that is exposed by removing the passivating dielectric layer from over the desired trench location. The trench surface may be sealed from moisture with a second application of a passivating dielectric such as silicon nitride, or alternatively, with the aluminum used to form the cap over the bond pad. FIGS. 8a to 8d show various steps in this process. In FIG. 8a passivating dielectric layer 108 is shown formed over interlevel dielectric layer 803 and bond pad 814. A photoresist mask layer 830 has been patterned to expose the locations of the window 716 over the bond pad 814 and the location of the trench. In FIG. 8b, the passivating dielectric layer 108 has been etched from these locations. In FIG. 8c, another etch step has been used to remove the portions of interlevel dielectric 803 exposed by the removal of the portion of passivation dielectric layer 108 over the desired location of trench 600.

At this point in the process, if the trench is in a location of the die in which moisture ingress is not a reliability concern, the aluminum cap 818 can be applied to pads 814, followed by the wire bonds and encapsulating mold compound dielectric 114. If, however, it is desirable to apply a moisture barrier to trench 600, a second passivating dielectric layer (not shown) can be applied to cover the surface of trench 600, or, in the alternative, aluminum liner 840 can be deposited during the formation of aluminum cap 818 to create the moisture barrier in the trench. As in the embodiment described above, slots 720 are formed in the cap metal 818 for enhanced adhesion of the mold compound to the die surface.

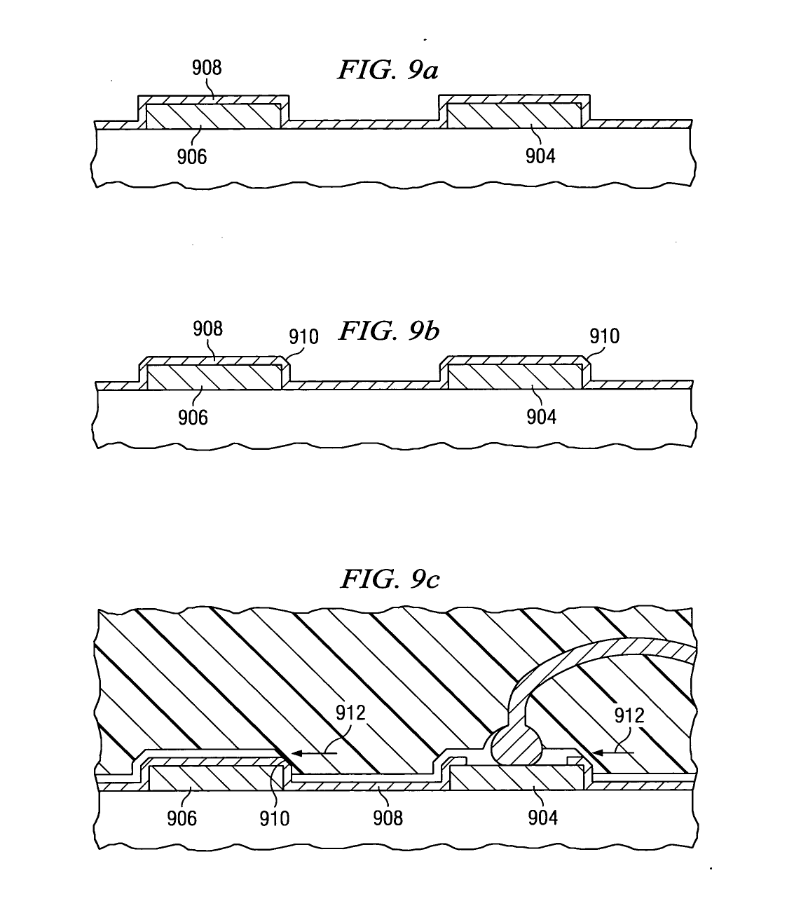

In another embodiment of the invention, potential damage resulting from the delamination of mold compound from the die surface can be reduced by shaping the passivating dielectric at the die surface to reduce lateral forces on metal features formed on the die. In FIG. 9a, the step-like projections of a bond pad 904 and a metal lead 906 are shown covered with a passivating dielectric 908. In FIG. 9b, the sides 910 of the step-like projections are sloped by, for example, sputtering the passivating dielectric layer 908 (either prior to opening the bond pad windows or following that step). The sloped profile of the dielectric on the step-like metal projections helps to reduce the lateral force (indicated by arrows 912) that is applied to the projections during shifting of the mold compound relative to the die surface as shown in FIG. 9c. This modification of the passivating dielectric is of particular benefit in reducing delamination-induced deformation of metal features such as bond pads and metal leads.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as claimed hereinbelow.

We claim:

1. A packaged integrated circuit, comprising:
a die having a surface and corners separated by edges, said die surface including depressions; and
mold compound covering said die surface and filling said depressions.

2. The packaged integrated circuit of claim 1, wherein said die comprises bond pads, and further wherein said depressions comprise slots in said bond pads.

3. The packaged integrated circuit of claim 1, wherein said depressions comprise trenches at the surface of said die in a dielectric layer.

4. The packaged integrated circuit of claim 3, wherein said trenches are at said corners of said die.

5. The packaged integrated circuit of claim 4, wherein said trenches are along said edges of said die.

6. The packaged integrated circuit of claim 1, wherein said surface of said die comprises step-like projections, and further wherein said die surface and said projections are covered with a passivating dielectric, wherein said dielectric covering said step-like projections has sloped edges.

7. A packaged integrated circuit, comprising:
a die comprising a stack of alternating patterned metal and dielectric layers;
a trench in said stack through at least one of said dielectric layers; and
mold compound covering said die and filling said trench.

8. The packaged integrated circuit of claim 7, wherein said stack includes a highest layer of patterned metal and a next-highest layer of patterned metal separated by an inter-level dielectric layer, and further wherein said trench is formed in said interlevel dielectric layer.

9. The packaged integrated circuit of claim 8, further comprising a dummy pad formed in said next-highest layer of patterned metal, wherein said trench is formed in said interlevel dielectric layer over said dummy pad.

10. The packaged integrated circuit of claim 7, wherein said trench is formed at a corner of said die.

11. The packaged integrated circuit of claim 7, wherein said trench is formed along the edges of said die.

12. The packaged integrated circuit of claim 7, wherein said die includes bond pads, said bond pads including slots.

13. The packaged integrated circuit of claim 7, wherein said die comprises step-like projections, and further wherein said die and said projections are covered with a passivating dielectric, wherein said dielectric covering said step-like projections has sloped edges.

14. A packaged integrated circuit, comprising:
a die including bond pads, wherein each of said bond pads comprise a central bonding region and a peripheral region, said peripheral region comprising at least one slot.

15. The packaged integrated circuit of claim 14, further comprising a passivating dielectric layer over said die, said passivating dielectric layer conformally covering said bond pad and said slots.

16. The packaged integrated circuit of claim 14, further comprising mold compound covering said die and filling said slots.

17. The packaged integrated circuit of claim 15 further comprising mold compound covering said die and filling said slots.

18. The packaged integrated circuit of claim 17 further comprising a trench in a surface of said die, wherein said mold compound fills said trench.

19. The packaged integrated circuit of claim 18, wherein said trench is at a corner of said die.

20. The packaged integrated circuit of claim 14, wherein said bond pads are covered with a passivating dielectric having sloped edges.
